(19) United States
(12) Patent Application Publication
(10) Pub. No.: US 2007/0029597 A1
(43) Pub. Date: Feb. 8, 2007

(54) HIGH-VOLTAGE SEMICONDUCTOR DEVICE

(76) Inventors: Jae-gil Lee, Gyeonggi-do (KR); Kyu-hyun Lee, Gyeonggi-do (KR); Ho-cheol Jang, Gyeonggi-do (KR); Chong-man Yun, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 11/460,755

(22) Filed: Jul. 28, 2006

(30) Foreign Application Priority Data
Jul. 30, 2005 (KR) 10-2005-0070026

(51) Int. Cl. H01L 29/94

(52) U.S. Cl. 257/302

(57) ABSTRACT

Provided is a high-voltage semiconductor device which is constructed such that the quantity of P and N charges are balanced in the entire drift region thereby preventing the degradation of the device breakdown characteristics. The high-voltage semiconductor device comprises an active region including N pillars of N conductivity type and P pillars of P conductivity type, arranged alternately in a direction from a center portion of the active region to an outer portion thereof to encircle each other in a horizontal direction. The N and P pillars are formed in a closed shape.

### CROSS-REFERENCE TO RELATED APPLICATION

This application claims priority to Korean Patent Application No. 10-2005-0070026, filed on Jul. 30, 2005 in the Korean Intellectual Property Office, which is incorporated herein by reference in its entirety for all purposes.

### BACKGROUND OF THE INVENTION

The present invention relates to a semiconductor device, and more particularly, to a high-voltage semiconductor device having an alternating conductivity type drift layer.

Generally, a vertical semiconductor device has electrodes on two planes facing each other. When the vertical semiconductor device is turned on, a drift current flows vertically. On the other hand, when the vertical semiconductor device is turned off, a depletion region is formed by an applied reverse bias voltage. The vertical semiconductor device can achieve a high breakdown voltage by forming a drift layer between the facing electrodes using a material of high resistivity, and increasing the thickness of the drift layer. This, however, increases the on-resistance and conduction loss of the device, and decreases the switching speed. It is well know in the art that the on-resistance increases in proportion to the 2.5-th power of the breakdown voltage.

To solve this problem, a semiconductor device with a new junction structure has been proposed. The proposed semiconductor device includes an alternating conductivity type drift layer having N regions (hereinafter referred to as N pillars) alternating with P regions (hereinafter referred to as P pillars). While the alternating conductivity type drift layer is used as a current path in the on-state of the device, it is depleted in the off-state of the device. A high-voltage semiconductor with the alternating conductivity type drift layer is called a super-junction semiconductor device.

FIG. 1 is a schematic layout view of a conventional super-junction semiconductor device 100. Super-junction semiconductor device 100 includes an active region 110, an edge P pillar 120 surrounding the active region 110, and a termination region 130 surrounding the edge P pillar 120. The edge P pillar 120 may be considered as part of the termination region 130. The edge P pillar 120 has the shape of a rounded rectangle. A plurality of active P pillars 110P and a plurality of active N pillars 110N are alternately arranged in the active region 110. The active P and N pillars 110 P and 110N have the shape of a stripe extending vertically. Although not illustrated in FIG. 1, a plurality of termination N pillars and a plurality of termination P pillars having the same shape as the edge P pillars 120 are alternately arranged in the termination region 130 and surround the edge P pillars 120.

FIG. 2 is a sectional view of the active region along line A-A′ in FIG. 1. Drift region 16, where the N pillars 110N and the P pillars 110P are alternately arranged, extends over the N+ substrate 12. A drain electrode 14 contacts a backside of substrate 12. P wells 18 are formed spaced apart from one another in an upper portion of the drift region 16. N+ source regions 20 are formed in the P wells 18, and N regions 22 are formed between neighboring P wells 18. A planar gate electrode 24 extends over N region 22 and partially overlaps the source regions 20, with an insulating layer 26 interposed between the gate electrode 24 and its underlying regions. A source electrode 28 insulated from gate electrodes 24 by the insulating layer 26 contacts source regions 20 and P wells 18. FIG. 1 is the layout view of a longitudinal section of the drift layer 16.

In general, the super-junction semiconductor device 100 is designed such that the termination region 130 has a higher breakdown voltage than the active region 100. The quantity of N charges and the quantity of P charges must be balanced in both the active region 110 and the termination region 130 for super-junction device 100 to have satisfactory breakdown characteristics. However, in FIG. 1, a charge imbalance exists between the quantity of N charges and the quantity of P charges at the interface between the vertically-extending active P pillars 110P and N pillars 110N and the horizontally-extending portions as well as the corner portions of the edge P pillar 120. This deteriorates the breakdown characteristics of the super-junction semiconductor device.

FIG. 3 shows a magnified view of the upper-left corner of the super-junction semiconductor device 100 illustrated in FIG. 1. The quantity of P charges in the active P pillar 110P and the quantity of N charges in the active N pillar 110N are balanced except in the corner portions C and where these vertically extending active N and P pillars interface the horizontally extending portions of the edge pillar 120. For example, in the case of a unit cell S1 in the active region 110, a first active P pillar 111 with left and right regions 111-1 and 111-2 divided by a vertical centerline, an active N pillar 112, and a second active P pillar 113 with left and right regions 113-1 and 113-2 divided by a vertical centerline, are sequentially arranged. The sum (Qp1+Qp2) of the quantity of P charges (Qp1) in the right region 111-2 of the first active P pillar 111 and the quantity of P charges (Qp2) in the left region 113-1 of the second active P pillar 113 is balanced with the quantity of N charges (Qn1) in the active N pillar 112 between the active P pillars 111 and 113. This charge balance exists through out the active region 110 except in corner portions C and where the vertically extending active N and P pillars 100N, 110P interface the horizontally extending portions of the edge pillar 120.

Likewise, in the termination region 130, the quantity of P charges in the termination P pillar 132 and the quantity of N charges in the termination N pillar 131 are distributed and balanced. For example, in the case of a unit cell S2 in the termination region 130, a termination N pillar 131 and a termination P pillar 132 are sequentially arranged outside the edge P pillar 120 with inner and outer regions 121 and 122 divided by a centerline. The termination P pillar 132 also has inner and outer regions 132-1 and 132-2 divided by a centerline. The sum (Qpe+Qpt1) of the quantity of P charges (Qpe) in the outer region 122 of the edge P pillar 120 and the quantity of P charges (Qpt1) in the inner region 132-1 of the termination P pillar 132 is balanced with the quantity of N charges (Qnt) in the termination N pillar 131. This charge balance similarly exists in the other portions of the termination region 130.

However, the P and N quantity of charges are seriously unbalanced at the upper, lower and corner portions of the active region 110 adjacent to the horizontally extending portions of edge P pillar 120. This is because there is no quantity of N charges to balance the quantity of P charges in the inner region 121 of the edge P pillar 120. Specifically, the P and N quantity of charges are balanced in the active region 110 along the vertically extending portions of the edge P pillar 120 due to the inner region 121 of the edge P pillar 120 and the active P and N pillars. Also, the P and N quantity of charges are balanced in the entire termination region 130 due to the outer region 122 of the edge P pillar 120 and the termination P and N pillars. However, the inner region 121 of the horizontally extending portions of edge P pillar 120 does not contribute to the charge balance at the corner and the upper and lower portions of the active region, causing a surplus quantity of P charges. This surplus quantity of P charges breaks the balance between the P and N quantity of charges, reducing the breakdown voltage and degrading the operation characteristics of the device.

### BRIEF SUMMARY OF THE INVENTION

The present invention provides a high-voltage semiconductor device constructed such that the quantity of P and N charges are balanced in the entire active region thereby preventing the degradation of the device breakdown characteristics.

According to an aspect of the present invention, there is provided a high-voltage semiconductor device including: an active region including N pillars of N conductivity type and P pillars of P conductivity type, wherein the N pillars and the P pillars are arranged alternately in a direction from a center portion of the active region to an outer portion thereof to encircle each other in a horizontal direction.

The center portion of the active region may be formed of only an N region or of a P region. The N and P pillars may be formed in a closed shape.

The N and P pillars may be cylindrical. The N and P pillars may be polygonal, such as rectangles or hexagons. The N and P pillars may be substantially rectangular and have curved beveled edge portions.

A quantity of N charges in the N pillars may be balanced with a quantity of P charges in the P pillars. Since the charge quantity is proportional to the concentration and volume (a sectional area in the case of a constant depth) of doped impurity ions, it can be adjusted according to the concentration and the sectional area.

Each of the P pillars may be divided into an inner P pillar and an outer P pillar by a center axis thereof, a sectional area ratio Aₙ/Aₚ between a sectional area Aₙ of each of the N pillars and a sum Aₚ of a sectional area of the inner P pillar surrounded by a corresponding N pillar and a sectional area of the outer P pillar surrounding a corresponding N pillar may be constant, and a sectional area ratio A_{nc}/A_{pc}, between a sectional area A_{nc} of the N region in the center region and a sectional area A_{pc} of an inner P pillar surrounding the center N region may be equal to the sectional area ratio Aₙ/Aₚ.

Alternatively, each of the N pillars may be divided into an inner N pillar and an outer N pillar by a center axis thereof, a sectional area ratio Aₚ/Aₙ between a sectional area Aₚ of each of the P pillars and a sum Aₙ of a sectional area of the inner N pillar surrounded by a corresponding P pillar and a sectional area of the outer N pillar surrounding a corresponding P pillar may be constant, and a sectional area ratio A_{pc}/A_{nc} between a sectional area A_{pc} of the P region in the center region and a sectional area A_{nc} of an inner N pillar surrounding the center P region is equal to the sectional area ratio Aₚ/Aₙ.

In one embodiment, a concentration of the N conductivity dopants in N pillars is identical to a concentration of the P conductivity dopants in the P pillars, and a sectional area ratio between the N and P pillars is 1. On the other hand, when a concentration of the N conductivity dopants in N pillars is different from a concentration of the P conductivity dopants in P pillars, a sectional area ratio between a sectional area of the N pillars and the P pillars is inversely proportional to the concentration ratio between the concentration of N conductivity dopants in N pillars and the concentration of P conductivity dopants in P pillars.

In another embodiment, the device includes a termination region surrounding the active region, and the termination includes N and P pillars arranged in the same way as in the active region. Here, each of the P pillars in the termination region may be divided into an inner P pillar and an outer P pillar by a center axis thereof, and a sectional area ratio Aₙₜ/Aₚₜ between a sectional area Aₙₜ of each of the N pillars and a sum Aₚₜ of a sectional area of the inner P pillar surrounded by a corresponding N pillar and a sectional area of the outer P pillar surrounding a corresponding N pillar may be equal to or different from the sectional area ratio Aₙ/Aₚ in the active region.

According to another aspect of the present invention, there is provided a high-voltage semiconductor device including: a semiconductor substrate with a voltage sustaining layer thereon; the voltage sustaining layer including N pillars of an N conductivity type and P pillars of P conductivity type, the N pillars and the P pillars being arranged alternately in a direction from a center portion of the active region to an outer portion thereof to encircle each other in a horizontal direction; a first impurity region is formed in an upper portion of the voltage sustaining layer; a second impurity region of a second conductivity type formed in the first impurity region; a first electrode making electrical contact to the first and second impurity regions; and a second electrode making electrical contact to the semiconductor substrate.

The device may be a MOSFET or an IGBT.

The first impurity region may be formed in plurality corresponding to the N and P pillars such that the first impurity regions are repeatedly arranged spaced apart from one another by a predetermined distance. The second electrode may be formed in plurality corresponding to the N pillars such that the second electrodes are repeatedly arranged spaced apart from one another by a predetermined distance.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic layout view of a conventional high-voltage semiconductor device;

FIG. 2 is a sectional view of an active region, taken along line A-A′ in FIG. 1;

FIG. 3 is an enlarged view of a corner of the high-voltage semiconductor device illustrated in FIG. 1;

FIG. 4 is a layout schematic view of a high-voltage semiconductor device according to a first embodiment of the present invention;

FIG. 5 is an enlarged view of a portion A in FIG. 4;

FIG. 6 is a schematic cross-sectional view of a MOS transistor with an active region according to an embodiment of the present invention;

FIG. 7 is a schematic view showing the arrangement of a gate electrode illustrated in FIG. 4;

FIG. 8 is a schematic layout view of a high-voltage semiconductor device according to a second embodiment of the present invention;

FIG. 9 is an enlarged view of a portion B in FIG. 8;

FIG. 10 is an enlarged view of a portion C in FIG. 9;

FIG. 11 is a schematic view of a high-voltage semiconductor device according to a third embodiment of the present invention;

FIG. 12 is an enlarged view of a portion D in FIG. 11;

FIG. 13 is a variation of the enlarged view in FIG. 12; and

FIG. 14 is an enlarged view of a portion E in FIGS. 12 and 13.

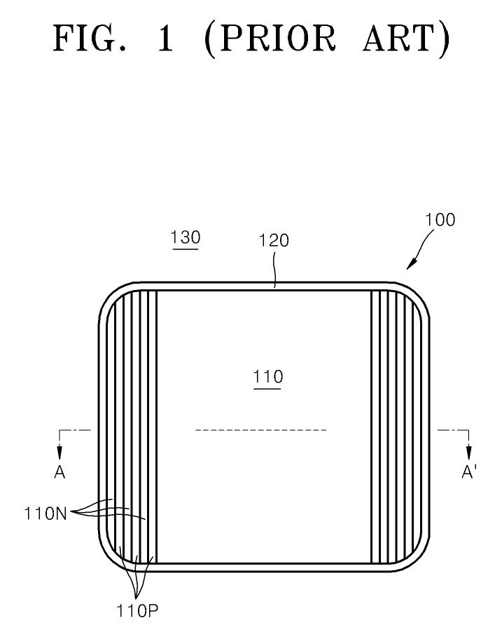

### DETAILED DESCRIPTION OF THE INVENTION

The present invention will now be described more fully with reference to the accompanying drawings, in which exemplary embodiments of the invention are shown. The invention may, however, be embodied in many different forms, and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. Like reference numerals denote like elements in the drawings, and thus their description will not be repeated.

In accordance with embodiments of the invention, a semiconductor power device includes N regions and P region alternately arranged in an active region of the device such that the N region and the P regions encircle one another in a substantially concentric fashion. The N and P regions may be any suitable geometrical shape such as circular, hexagonal with rounded comers, or square or rectangular with rounded corners. The power device may be N-channel or P-channel MOSFET or IGBT with planar gate, trench gate, or shielded gate structures. In such devices, the concentric arrangement of the alternating N and P regions results in charge balance throughout the active region including along its outer periphery, as well as in the termination region. Thus, power devices with superior breakdown characteristics are obtained.

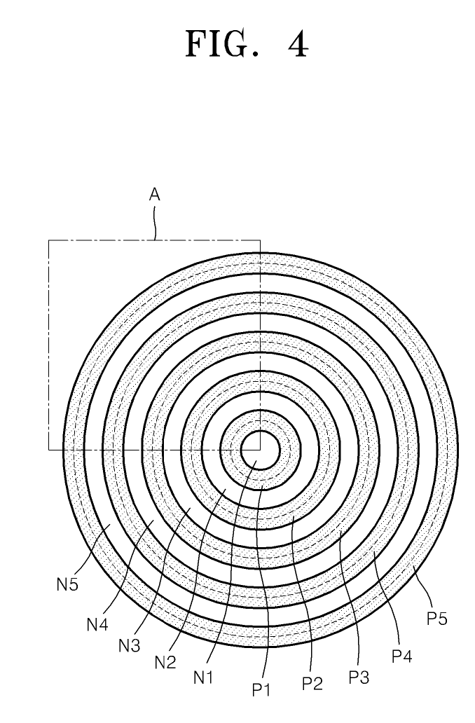

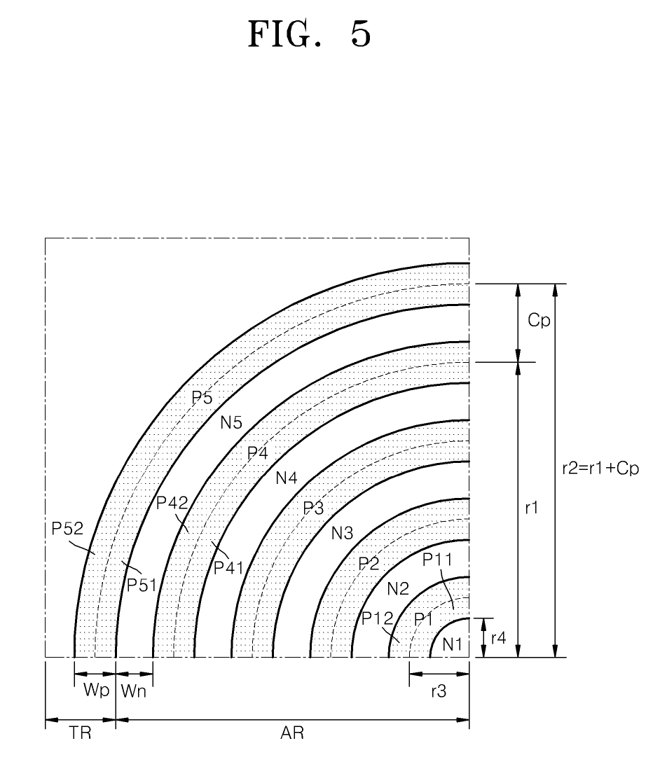

FIG. 4 is a schematic layout view illustrating active and termination regions of a high-voltage semiconductor device (hereinafter also referred to as a super-junction semiconductor device) according to a first embodiment of the present invention, and FIG. 5 is an enlarged view of a portion A in FIG. 4. The active region denotes a region where donut-shaped N and P pillars are alternately formed. Also, the pillars denote not only a solid cylindrical pillar at a center portion of the active region, but also hollow cylindrical or polygonal pillars surrounding the solid cylindrical pillar.

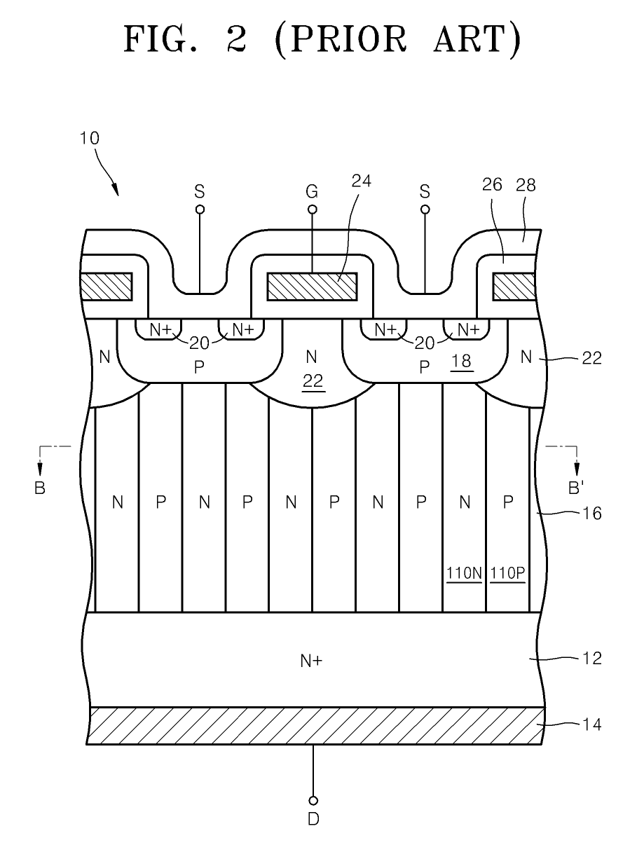

Referring to FIGS. 4 and 5, the active and termination regions include N pillars N1, N2, . . . , N5, . . . of an N conductivity type and P pillars P1, P2, . . . P5, . . . of a P conductivity type, arranged concentrically on a horizontal plane. Sections of the N and P pillars are illustrated in FIGS. 4 and 5. The sections correspond to the active and termination region corresponding to line B-B′ in FIG. 2, and in one embodiment, the pillars have a substantially constant height.

As illustrated in FIG. 5, an active region AR is formed from the center (region N1) out to a certain radius, and a termination region TR is formed outside that radius. That is, the termination region TR surrounds the active region AR. Accordingly, the N and P pillars are alternately arranged in both the active and termination regions. In case of a high-voltage semiconductor device with the opposite conductivity, the conductivity type of the center portion is changed to P1 and conductivity type of all other pillars is reversed.

A first N pillar N1 is at the center portion of the active region, a first P pillar P1 surrounds the first N pillar N1, and a second N pillar N2 surrounds the first P pillar P1. Likewise, the second N pillar N2 is surrounded by a second P pillar P2, and the second P pillar P2 is surrounded by a third N pillar N3. In this manner, the N and P pillars are arranged concentrically and repeatedly in the order of N1/P1/N2/P2/N3/P3/N4/P4/N5/P5/N6/P6 etc.

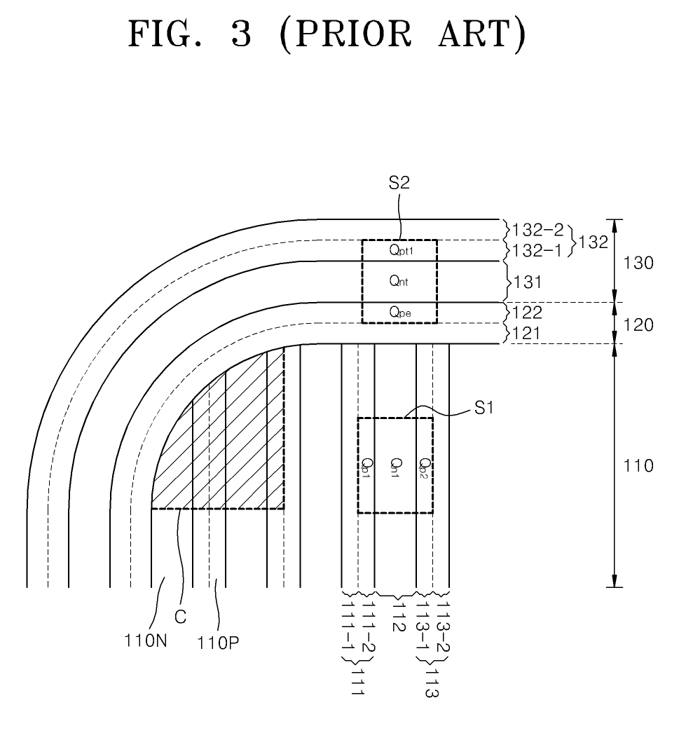

In one example where the fifth P pillar P5 is set to correspond to the edge P pillar 120 in FIG. 3, the first through fifth N pillars N1 through N5 constitute the active region AR and an outward portion from a sixth N pillar (not shown) formed around the fifth P pillar P5 constitutes the termination region TR. Alternatively, the fifth P pillar P5 may be included in the termination region TR.

The charge balance relationship between the P pillars and the N pillars will now be described in detail. In general, the quantity Q of charge contained in a volume V is proportional to the volume V and the concentration C of impurity ions. That is, Q=C×V. Referring to FIG. 4, the quantity Q of charge contained in the N and P pillars is proportional to the volume V of the pillars and the concentration C of impurity ions contained in the pillars. When the N and P pillars have the same height, the same impurity ion concentration C, the volume of the N and P pillars is proportional to the sectional area A of the pillars as shown in FIG. 4. Therefore, the charge quantity Q can be expressed as kC×A. That is, Q=k×C×A. Consequently, when the concentration C is constant, the charge quantity Q is proportional to the sectional area. On the other hand, when the sectional area is constant, the charge quantity Q is proportional to the concentration C. When the concentration C varies, the charge quantity Q can be maintained constant by adjusting the sectional area A. Also, when the concentration C varies along the horizontal or vertical dimension, the charge quantity can be maintained constant by adjusting the volume V or the sectional area A of the pillars.

The charge balance relationship between neighboring N and P pillars, for example, between the fourth P pillar P4, the fifth N pillar N5 and the fifth P pillar P5, will now be described with reference to FIG. 5. Although the charge balance relationship is described with respect to a sectional area ratio where the impurity ion concentration of the pillars is uniform over the entire active region, the present invention can also be applied to cases where the impurity ion concentration varies.

The fourth P pillar P4 can be divided into a fourth inner P pillar P41 and a fourth outer P pillar P42 by a center axis extending along a circumferential direction. Likewise, the fifth P pillar P5 can be divided into a fifth inner P pillar P51 and a fifth outer P pillar P52 by a center axis extending along the circumferential direction. The radial width of the fourth or fifth P pillar P4 or P5 is denoted as Wₚ, and the radial width of the fifth N pillar N5 is denoted as Wₙ. The radius from the center of the first N pillar N1 to the center axis of the fourth P pillar P4 is denoted as r1. The distance from the center axis of the fourth P pillar P4 to the center axis of the fifth P pillar P5 is denoted as Cₚ (=Wₚ+Wₙ). The radius from the center of the first N pillar N1 to the center axis of the first P pillar P1 is denoted as r3. The radius from the center of the first N pillar N1 to the center axis of the fifth P pillar P5 is denoted as r2, and r2=r1+Cₚ. A central angle is denoted as θ, and θ is π/2 in the case of the quadrant in FIG. 5.

The sectional area Aₙ, of the fifth N pillar N5 can be expressed as Equation 1 below.

$${A}_{n} = \frac{θ}{2} [ {( {r}_{2} - 0.5 {W}_{p} )}^{2} - {( {r}_{1} + 0.5 {W}_{p} )}^{2} ] = \frac{θ}{2} [ ( {r}_{1} + {r}_{2} ) {W}_{n} ] \qquad ( Eq . 1 )$$

The sum Aₚ of the sectional area of the fourth outer P pillar P42 and the sectional area of the fifth inner P pillar P51 can be expressed as Equation 2 below.

$$\begin{matrix}{A}_{p} = \frac{θ}{2} [ \{ {r}_{2} 2 - {( {r}_{2} - 0.5 {W}_{p} )}^{2} \} - \{ {( {r}_{1} + 0.5 {W}_{p} )}^{2} - {r}_{1} 2 \} ] \\ = \frac{θ}{2} [ ( {r}_{1} + {r}_{2} ) {W}_{p} ]\end{matrix} \qquad ( Eq . 2 )$$

A sectional area ratio Aₚ/Aₙ between the sum Aₚ and the sectional area Aₙ of the fifth N pillar N5 can be expressed as Equation 3 below.

$$\frac{{A}_{p}}{{A}_{n}} = \frac{{W}_{p}}{{W}_{n}} \qquad ( Eq . 3 )$$

As can be seen from Equation 3, the sectional area ratio between the neighboring P and N pillars has a constant value of Wₚ/Wₙ. When the P and N pillars have the same concentration and the width Wₙ of the N pillar is equal to the width Wₚ of the P pillar, the section area ratio Wₚ/Wₙ is 1.

Accordingly, full charge balance can be obtained between the neighboring P and N pillars in the entire active and termination regions AR and TR, except between a first N pillar N1 and a first inner P pillar P11. Consequently, it is possible to keep a constant relationship between the charge quantity ratio, the sectional area ratio, and the radial width ratio throughout the entire active region except the center portion.

A method of determining the sectional ratio relationship between the first N pillar N1 and the first inner P pillar P11, specifically the width of the first N pillar N1, will now be described. Referring to FIG. 5, the first P pillar P1 can be divided into the first inner P pillar P11 and a first outer P pillar P12 by a center axis extending along the circumferential direction. The sectional area A_{nc} of the first N pillar N1 having a central angle θ can be expressed as Equation 4 below.

$${A}_{nc} = \frac{θ}{2} {( {r}_{3} - 0.5 {W}_{p} )}^{2} \qquad ( Eq . 4 )$$

The sectional area A_{pc} of the first inner P pillar P11 can be expressed as Equation 5 below.

$${A}_{pc} = \frac{θ}{2} \{ {r}_{3} 2 - {( {r}_{3} - 0.5 {W}_{p} )}^{2} \} = \frac{θ}{2} ( {r}_{3} {W}_{p} - \frac{{W}_{p}^{2}}{4} ) \qquad ( Eq . 5 )$$

For the constant charge balance with the other pillars, the sectional area ratio A_{pc}/A_{nc} between the first N pillar N1 and the first inner P pillar P12 must have a value of Wₚ/Wₙ as expressed by Equation 3. This can be expressed as Equation 6 below. Also, Equation 6 results in Equation 7 below.

$$\begin{matrix}\frac{{A}_{pc}}{{A}_{nc}} = \frac{{W}_{p}}{{W}_{n}} = \frac{{A}_{p}}{{A}_{n}} & ( Eq . 6 ) \\ {r}_{3} = \frac{( {W}_{p} + {W}_{n} ) + \sqrt{{W}_{n} ( {W}_{p} + {W}_{n} )}}{2} = 0.5 {W}_{p} + {r}_{4} & ( Eq . 7 )\end{matrix}$$

That is, when the width of the first N pillar N1 is determined according to Equation 7, the entire active region AR has a constant sectional ratio Wₚ/Wₙ. For example, when Wₚ=3 μm and Wₙ=6 μm, r3=8.2 μm and r4=6.7 μm. This yields charge balance throughout the entire active region, including the center portion.

When the termination region TR has a constant pillar width, it is possible to keep a charge balance between the neighboring P and N pillars throughout the active and termination regions AR and TR. Accordingly, the lower breakdown voltage at the perimeter of the active region in the prior art approaches is prevented, thus enabling fabrication of high-voltage semiconductor devices with improved breakdown characteristics.

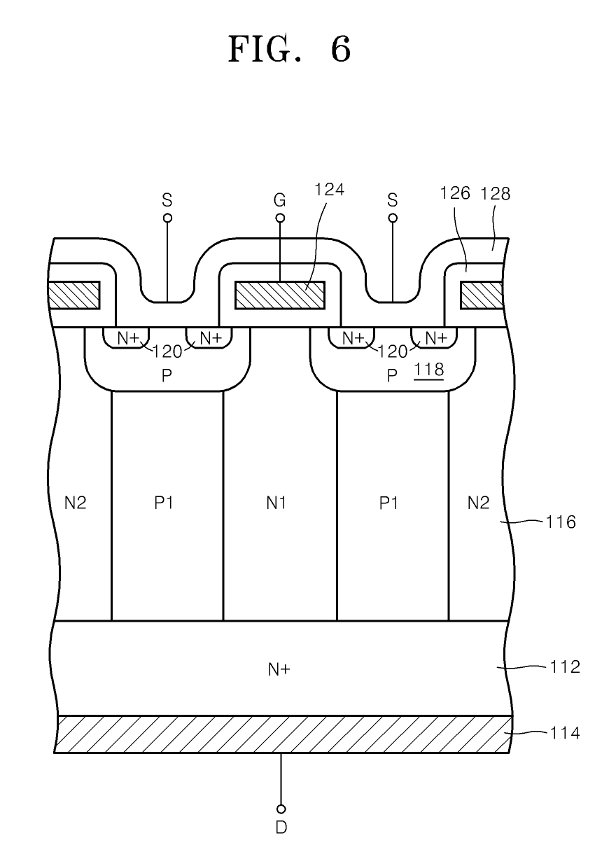

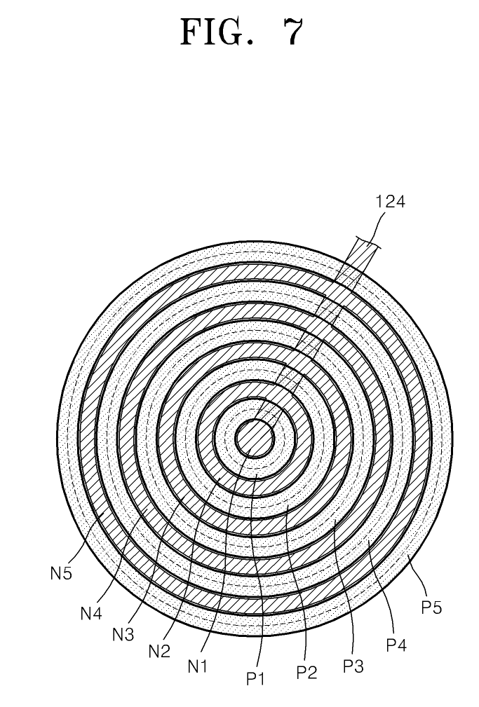

FIG. 6 is a schematic cross-sectional view of a high-voltage MOSFET that is an example of the high-voltage semiconductor device with the active region according to the first embodiment of the present invention, and FIG. 7 is a corresponding plan view of the arrangement of a gate electrode illustrated in FIG. 4.

Referring to FIG. 6, a voltage sustaining layer 116 (e.g., an n-type epitaxial layer) e housing the P and N pillars extends over a semiconductor substrate 112 of N+ conductivity type. P-type well regions 118 of P conductivity type extend over P pillars P1 in voltage sustaining layer 116. Source regions 120 spaced apart from each other are formed in the P-type well regions 118. A planar gate electrode 124 extends over each of N pillars N1, N2, etc. and overlaps well regions 118 and source regions 120, with a gate insulating layer 126 interposed therebetween. A source electrode 128 is formed on the resulting structure. A drain electrode 114 is formed on the lower surface of the semiconductor substrate 112 to construct a vertical MOSFET.

Referring to the layout view in FIG. 7, the gate electrodes 124 are located to correspond to the respective N pillars in the voltage sustaining layer 116, and are commonly connected to an external terminal.

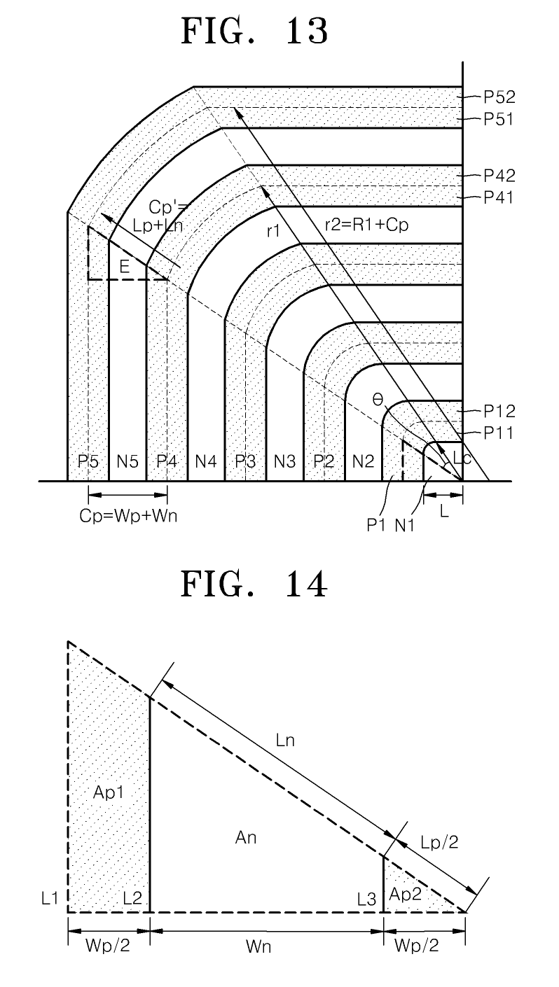

The vertical MOSFET structure in FIGS. 6 and 7 are provided as an example of a power device in which the present invention can be implements, and as such the present invention is not limited to this structure. In addition to the planar gate MOSFET shown in FIGS. 6 and 7, the various charge balance techniques disclosed herein may be integrated with other MOSFET varieties such as trench gate or shielded gate structures, as well as other power devices such as IGBTs and bipolar transistors. For example, the various embodiments of the present invention disclosed herein may be integrated with any of the devices shown for example, in FIGS. 14, 21-24, 28A-28D, 29A-29C, 61A, 62A, 62B, 63A of the U.S. patent application Ser. No. 11/026,276, filed Dec. 29, 2004 which disclosure is incorporated herein by reference in its entirety for all purposes.

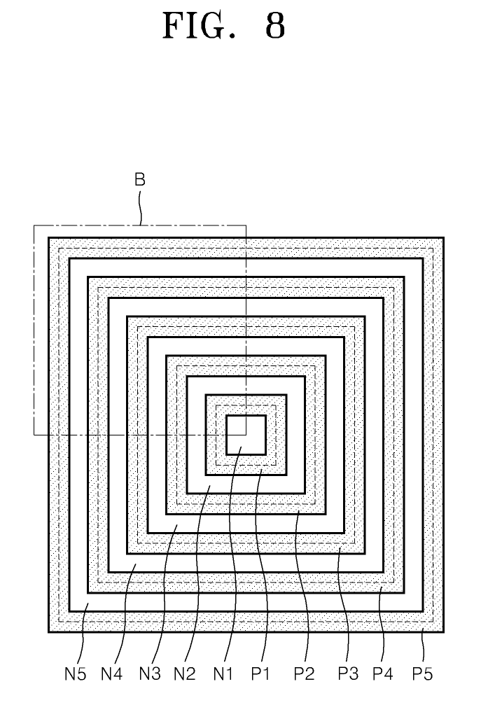

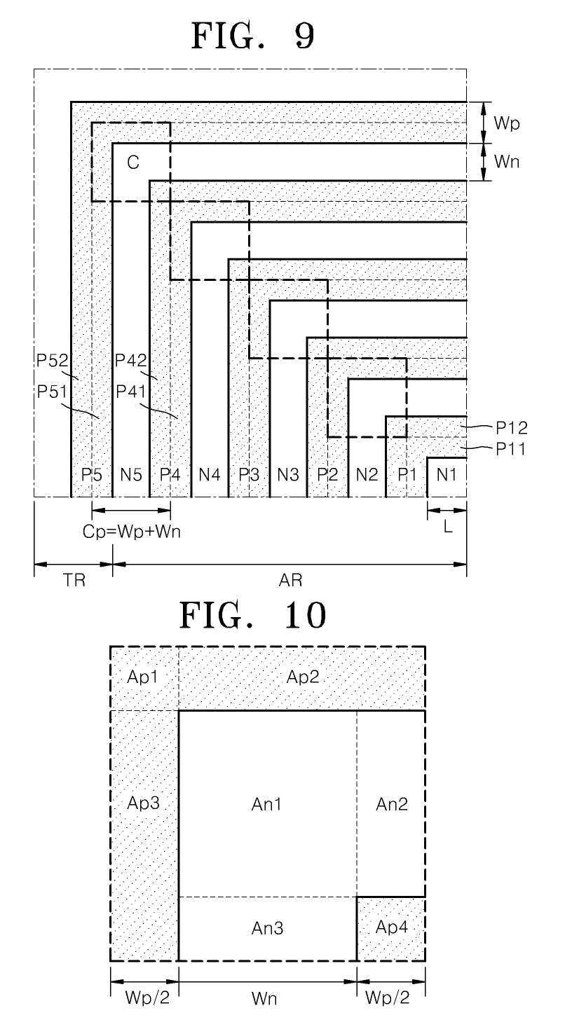

FIG. 8 is a schematic layout view of a super-junction semiconductor device according to a second embodiment of the present invention, FIG. 9 is an enlarged view of a portion B in FIG. 8, and FIG. 10 is an enlarged view of a portion (unit cell) C in FIG. 9. In the second embodiment, rectangular N and P pillars are formed repeatedly and alternately in a concentric fashion in the active region. The detailed description of aspects common to the first embodiment will be omitted.

Referring to FIG. 8, the active and termination regions include N pillars N1, N2, . . . , N5, . . . of an N conductivity type and P pillars P1, P2, . . . P5, . . . of a P conductivity type, arranged concentrically. The sections along a plane of the N and P pillars are illustrated in FIG. 8. The sections correspond to the active and termination regions along a plane corresponding to line B-B′ in FIG. 2, and in one embodiment, the pillars have a substantially constant height.

As illustrated in FIG. 9, an active region AR extends from the center (region N1) out to a certain radius, and a termination region TR is surrounds the active region AR. Accordingly, the N and P pillars are alternately arranged in a concentric fashion in the active and termination regions. The charge balance relationship between the P pillars and the N pillars will now be described in detail with reference to FIGS. 9 and 10.

Like the first embodiment, when the N and P pillars have the same height and a uniform impurity ion concentration C, the charge quantity Q is proportional to the sectional area A. On the other hand, when the N and P pillars have the same height and a constant sectional area, the charge quantity Q is proportional to the concentration C. When the concentration C varies, the same charge quantity Q can be maintained by adjusting the sectional area A. The second embodiment relates to a case where the concentration C in the pillars is constant as in the first embodiment.

The charge balance relationship between the neighboring N and P pillars, for example, between the fourth P pillar P4, the fifth N pillar N5 and the fifth P pillar P5, will now be described with reference to FIG. 9. The sectional area ratio between the neighboring N and P pillars is constant except at corner portions represented by a dotted line. That is, the fourth P pillar P4 can be divided into a fourth inner P pillar P41 and a fourth outer P pillar P42 by a center axis extending along a circumferential direction. Likewise, the fifth P pillar P5 can be divided into a fifth inner P pillar P51 and a fifth outer P pillar P52 by a center axis extending along a circumferential direction. The width of the fourth or fifth P pillar P4 or P5 is marked as Wₚ and the width of the fifth N pillar N5 is marked as Wₙ. The sectional area ratio Ap/An is the width ratio Wₚ/Wₙ except at corner regions C.

The charge balance relationship between the P and N pillars at the corner portions, and the charge balance relationship between a first N pillar N1 and a second inner P pillar P11, will now be described. Referring to FIG. 10, the sectional area Aₙ of the fifth N pillar N5 at the unit cell C can be expressed as Equation 8 below. Aₙ=Aₙ₁+Aₙ₂+Aₙ₃=Aₙ₁+2Aₙ₂=Wₙ(Wₚ+Wₙ) (Eq. 8)

The sum Aₚ of the sectional area of the fourth outer P pillar P42 and the sectional area of the fifth inner P pillar 51 can be expressed as Equation 9 below. Aₚ=Aₚ₁+Aₚ₂+Aₚ₃+Aₚ₄+2Aₚ₁+2Aₚ₂=Wₚ(Wₚ+Wₙ) (Eq. 9)

A sectional area ratio Aₚ/Aₙ between the sum Aₚ and the sectional area Aₙ of the fifth N pillar N5 can be expressed as Equation 10 below.

$$\frac{{A}_{p}}{{A}_{n}} = \frac{{W}_{p}}{{W}_{n}} \qquad ( Eq . 10 )$$

As can be seen from Equation 10, the sectional area ratio between the neighboring P and N pillars at each unit cell C has a constant value of Wₚ/Wₙ as in the stripe region. That is, the unit cell C has the same sectional area ratio as the stripe region. When the P and N pillars have the same concentration and the width Wₙ of the N pillars is the same as the width Wₚ of the P pillars, the section area ratio Wₚ/Wₙ is 1.

Accordingly, full charge balance can be obtained between the neighboring P and N pillars in the entire active and termination regions AR and TR, except between a first N pillar N1 and a first inner P pillar P11. Consequently, it is possible to keep a constant relationship between the charge quantity ratio, the sectional area ratio, and the radial width ratio throughout the entire active region except at the center portion.

A method of determining the sectional area ratio relationship between the first N pillar N1 and the first inner P pillar P11 will now be described. When the length of one side of the first N pillar N1 is L, the sectional area A_{nc} of the first N pillar N1 can be expressed as Equation 11 below.
A_{nc}=L² (Eq. 11)

The sectional area A_{pc} of the first inner P pillar P11 can be expressed as Equation 12 below.
A_{pc}=(r₃+0.5Wₚ)²−L² (Eq. 12)

For a constant charge balance with the other pillars, the sectional area ratio A_{pc}/A_{nc} between the first N pillar N1 and the first inner P pillar P12 must have the value of Wₚ/Wₙ as expressed by Equation 10. This can be expressed as Equation 13 below. Also, Equation 13 results in Equation 14 below.

$$\frac{{A}_{pc}}{{A}_{nc}} = \frac{{W}_{p}}{{W}_{n}} = \frac{{A}_{p}}{{A}_{n}} \qquad ( Eq . 13 )$$

From Equations 11 and 12, the length L can be expressed as Equation 14.

$$L = \frac{{W}_{n} + \sqrt{{W}_{n} ( {W}_{p} + {W}_{n} )}}{2} \qquad ( Eq . 14 )$$

That is, when the side length L of the first N pillar N1 is set according to Equation 14, the entire active region AR has a constant sectional ratio Wₚ/Wₙ. For example, when Wp=3 μm and Wn=6 μm, L=6.7 μm. This yields charge balance throughout the entire active region, including the center portion.

When the termination region TR has a constant pillar width, it is possible to keep a charge balance between the neighboring P and N pillars throughout the active and termination regions AR and TR. Accordingly, the lower breakdown voltage at the perimeter of the active region in the prior art approaches is prevented thus enabling fabrication of high-voltage semiconductor devices with improved breakdown characteristics. Particularly, when the active and termination regions have the rectangular shape, it is possible to maximize the usable chip area because a semiconductor wafer is cut into rectangular dies. According to the second embodiment, the source region of the MOSFET may have a repeated rectangular shape and the gate electrode may also have a rectangular shape corresponding to the N pillar. Note that while the rectangular N and P pillars are shown in FIGS. 8- 10 to have sharp corners, in practice (i.e., an actual fabricated device), the rectangular pillars may have slightly rounded corners.

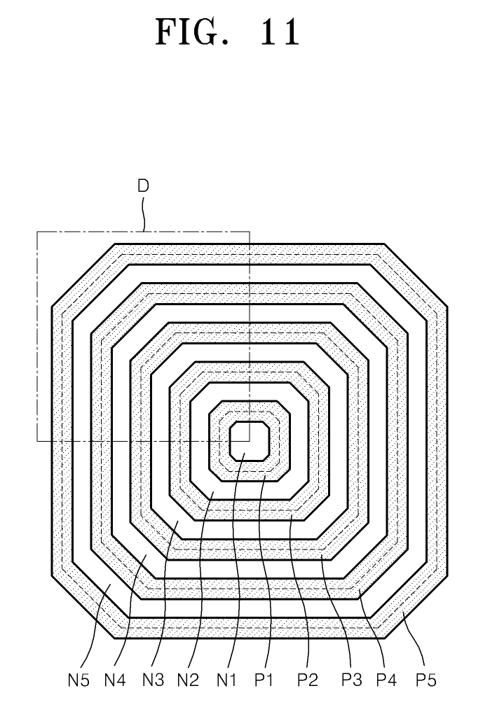

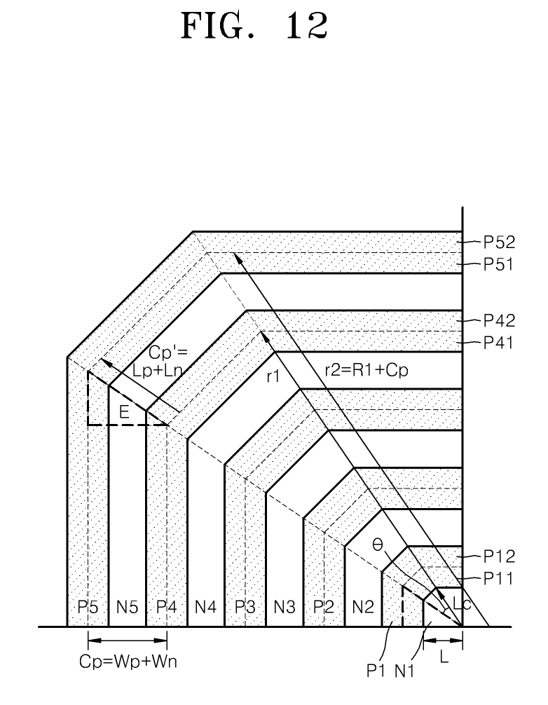

FIG. 11 is a schematic view of a super-junction semiconductor device according to a third embodiment of the present invention, FIG. 12 is an enlarged view of a portion (fourth quadrant) D in FIG. 11, FIG. 13 is an alternative implementation of the corner regions D, and FIG. 14 is an enlarged view of a portion (unit cell) E in FIGS. 12 and 13.

In the third embodiment, rectangular-type N and P pillars are formed repeatedly and alternately in active and termination regions in a concentric fashion. Unlike the second embodiment, the N and P pillars have flat (FIG. 12) or curved (FIG. 13) beveled corner portions. The embodiment in FIG. 12 corresponds to an example of the polygonal active region. The active region in FIG. 12 may have a regular octagonal shape depending on the size of the edge portion. The detailed description of aspects common to the first and second embodiments will be omitted.

Referring to FIG. 11, the active region includes N pillars N1, N2, . . . N5, . . . of an N conductivity type and P pillars P1, P2, . . . P5, . . . of a P conductivity type, arranged concentrically. The sections along a plane of the N and P pillars are illustrated in FIG. 11 The sections correspond to the active and termination regions along a plane corresponding to line B-B′ in FIG. 2, and in one embodiment, the polygonal N and P pillars have a substantially constant height. The polygonal N and P pillars are alternately arranged in a concentric fashion in the active and termination regions. The charge balance relationship between the P pillars and the N pillars will now be described in detail with reference to FIGS. 12 through 14.

First, the charge balance relationship between the neighboring N and P pillars (for example, the fourth P pillar P4, the fifth N pillar N5, and the fifth P pillar P5) will be described in detail with reference to FIGS. 12 and 13. The sectional area ratio between the neighboring N and P pillars is maintained constant except at the corner portions. That is, the fourth P pillar P4 can be divided into a fourth inner P pillar P41 and a fourth outer P pillar P42 by a center axis extending along a circumferential direction. Likewise, the fifth P pillar P5 can be divided into a fifth inner P pillar P51 and a fifth outer P pillar P52 by a center axis extending along the circumferential direction. The width of the fourth or fifth P pillar P4 or P5 is marked as Wₚ and the width of the fifth N pillar N5 is marked as Wₙ. The sectional area ratio Aₚ/Aₙ is the width ratio Wₚ/Wₙ except at the corner portions and regions E. Meanwhile, since the corner portions also have a stripe shape, their sectional area ratio is Lₚ/Lₙ that is identical to Wₚ/Wₙ (Lₚ=Wₚ sec(45−0.5θ), Lₙ=Wₙ sec(45−0.5θ)).

The charge balance relationship between the P and N pillars at the region E and the charge balance relationship between the first N pillar N1 and a second inner P pillar P11, specifically the sectional area ratio, will now be described. Referring to FIG. 14, the sectional area Aₙ of the fifth N pillar N5 at the region E can be expressed as Equation 15 below.

$${A}_{n} = \frac{1}{2} ( {L}_{2} + {L}_{3} ) {W}_{n} = \frac{{W}_{n}}{2} ( {W}_{p} + {W}_{n} ) tan ( 45 - \frac{θ}{2} ) \qquad ( Eq . 15 )$$

The sum Aₚ of the sectional area of the fourth outer P pillar P42 and the sectional area of the fifth inner P pillar 51 can be expressed as Equation 16 below.

$$\begin{matrix}{A}_{p} = {A}_{p 1} + {A}_{p 2} \\ = \frac{{W}_{p}}{4} ( {L}_{1} + {L}_{2} + {L}_{3} ) \\ = \frac{{W}_{p}}{2} ( {W}_{p} + {W}_{n} ) tan ( 45 - \frac{θ}{2} )\end{matrix} \qquad ( Eq . 16 )$$

In Equations 15 and 16, L1=(Wp+Wn)tan(45-0.5θ), L2=(0.5Wp+Wn)tan(45−0.5θ), and L3=0.5Wp tan(45−0.5θ). Here, θ is the center angle of the wedge portion corresponding to the corner portion in FIGS. 12 and 13. The sectional area ratio Aₚ/Aₙ between the sum Aₚ and the sectional area Aₙ of the fifth N pillar N5 can be expressed as Equation 17 below.

$$\frac{{A}_{p}}{{A}_{n}} = \frac{\frac{{W}_{p}}{2} ( {W}_{p} + {W}_{n} ) tan ( 45 - \frac{θ}{2} )}{\frac{{W}_{n}}{2} ( {W}_{p} + {W}_{n} ) tan ( 45 - \frac{θ}{2} )} = \frac{{W}_{p}}{{W}_{n}} \qquad ( Eq . 17 )$$

As can be seen from Equation 17, the sectional area ratio between the neighboring P and N pillars has a constant value of Wₚ/Wₙ as in the stripe region. That is, the unit cell E has the same sectional area ratio as the stripe region. When the P and N pillars have the same concentration and width, the section area ratio Wₚ/Wₙ is 1.

A method of keeping a constant charge quantity relationship between the first N pillar N1 and the first inner P pillar P11 will now be described in detail. When the length of one side of the first N pillar N1 is L, the sectional area A_{nc} of the first N pillar N1 can be expressed as Equation 18 below.

$${A}_{nc} = \frac{1}{2} {L}^{2} tan ( 45 - \frac{θ}{2} ) \qquad ( Eq . 18 )$$

The sectional area A_{pc} of the first inner P pillar P11 can be expressed as Equation 19 below.

$${A}_{pc} = \frac{1}{2} ( {W}_{p} L + \frac{{W}_{p}^{2}}{4} ) tan ( 45 - \frac{θ}{2} ) \qquad ( Eq . 19 )$$

The sectional area ratio A_{pc}/A_{nc} between the first N pillar N1 and the first inner P pillar P12 must have the value of Wₚ/Wₙ as expressed by Equation 20 below. Consequently, the length L can be expressed as Equation 21 below.

$$\frac{{A}_{pc}}{{A}_{nc}} = \frac{{W}_{p}}{{W}_{n}} = \frac{{A}_{p}}{{A}_{n}} \qquad ( Eq . 20 )$$

From Equations 18 and 19, the length L can be expressed as Equation 21.

$$L = \frac{{W}_{n} + \sqrt{{W}_{n} ( {W}_{p} + {W}_{n} )}}{2} \qquad ( Eq . 21 )$$

That is, when the side length L of the first N pillar N1 is set according to Equation 21, the entire active region AR has a constant sectional ratio Wp/Wn. For example, when Wp=3 μm and Wn=6 μm, L=6.7 μm. This yields charge balance throughout the entire active region, including the center portion.

The charge balance relationship between the neighboring N and P pillars in the rounded wedge portion will now be described in detail with reference to FIG. 13. Since expanding the rounded wedge portion results in the pillars taking a cylindrical shape similar to those in the first embodiment, the calculation can be made similarly to that for the first embodiment. In the rounded wedge portion, Lₙ is the width of the fifth N pillar, Lₚ is the width of the fourth or fifth pillar, and θ is the center angle of the rounded wedge portion. Here, Lₚ=Wₚ sec(45−0.5θ), Lₙ=Wₙ sec(45−0.5θ).

The sectional area Aₙ of the fifth N pillar N5 can be expressed as Equation 22 below.

$${A}_{n} = \frac{θ}{2} [ {( {r}_{2} - 0.5 {L}_{p} )}^{2} - {( {r}_{1} + 0.5 {L}_{p} )}^{2} ] = \frac{θ}{2} [ ( {r}_{1} + {r}_{2} ) {L}_{n} ] \qquad ( Eq . 22 )$$

The sum Aₚ of the sectional area of the fourth outer P pillar P42 and the sectional area of the fifth inner P pillar 51 can be expressed as Equation 23 below.

$$\begin{matrix}{A}_{p} = \frac{θ}{2} [ \{ {r}_{2} 2 - {( {r}_{2} - 0.5 {L}_{p} )}^{2} \} + \{ {( {r}_{1} + 0.5 {L}_{p} )}^{2} - {r}_{1} 2 \} ] \\ = \frac{θ}{2} [ ( {r}_{1} + {r}_{2} ) {L}_{p} ]\end{matrix} \qquad ( Eq . 23 )$$

The sectional area ratio Aₚ/Aₙ between the sum Aₚ and the sectional area Aₙ of the fifth N pillar N5 can be expressed as Equation 24 below.

$$\frac{{A}_{p}}{{A}_{n}} = \frac{{L}_{p}}{{L}_{n}} = \frac{{W}_{p}}{{W}_{n}} \qquad ( Eq . 24 )$$

As can be seen from Equation 24, the sectional area ratio between the neighboring P and N pillars has the constant value of Wₚ/Wₙ at this region in all of the pillars. The radius of curvature of the first N pillar N1 is marked as Lc (=L sec(45−0.5θ)), and the sectional area A_{nc} of the first N pillar N1 can be expressed as Equation 25 below.

$${A}_{nc} = \frac{θ}{2} {( {L}_{c} )}^{2} \qquad ( Eq . 25 )$$

The sectional area A_{pc} of the first inner P pillar P11 can be expressed as Equation 26 below.

$${A}_{pc} = \frac{θ}{2} \{ {( {L}_{c} + \frac{{L}_{p}}{2} )}^{2} - {( {L}_{c} )}^{2} \} = \frac{θ}{2} ( {L}_{c} {L}_{p} - \frac{{L}_{p}^{2}}{4} ) \qquad ( Eq . 26 )$$

For a constant charge balance with the other pillars, the sectional area ratio A_{pc}/A_{nc} between the first N pillar N1 and the first inner P pillar P12 must have the value of Wₚ/Wₙ as expressed by Equation 27 below. Consequently, the length L can be expressed as Equation 28 below.

$$\frac{{A}_{pc}}{{A}_{nc}} = \frac{{W}_{p}}{{W}_{n}} = \frac{{A}_{p}}{{A}_{n}} \qquad ( Eq . 27 )$$

From Equations 25 through 27, the length L can be expressed as Equation 28.

$$L = \frac{{W}_{n} + \sqrt{{W}_{n} ( {W}_{p} + {W}_{n} )}}{2} \qquad ( Eq . 28 )$$

That is, when the side length L of the first N pillar N1 is set according to Equation 28, charge balance can be achieved for the entire active region AR. For example, when Wₚ=3 μm and Wₙ=6 μm, L=6.7 μm.

When the corner portion has a flat bevel as illustrated in FIG. 12, the method for the region E in the third embodiment can be applied to deduce a relational equation identical to Equation 27.

In summary, charge balance between the neighboring P and N pillars is achieved throughout the active and termination regions AR and TR. Accordingly, the lower breakdown voltage at the perimeter of the active region is the prior art approaches is prevented thus enabling fabrication of high-voltage semiconductor devices with improved breakdown voltage characteristics.

The foregoing descriptions have not covered all details of the entire structure of the various super-junction semiconductor devices, since the active and termination regions can be formed on a semiconductor substrate through conventional techniques, such as the well known multi-epitaxy technique and the trench technique. The drain electrode of a MOSFET (or collector electrode of an IGBT) can be formed on the lower surface of the semiconductor substrate. The plurality of source (or emitter) regions and the well regions including the source regions can be formed on the active and termination regions by conventional ion implantation techniques. The gate electrode and gate insulating layer can be formed on the active region in the case of planar gate transistors, or in a trench in the case of trench gate transistors. The gate insulating layer is deposited on the entire surface of the structure after forming the gate electrode pattern. Thereafter, a pattern for exposing a portion of the source (or emitter) regions is formed and then a conductive material is deposited on the resulting structure to form the source (emitter) electrode, resulting in a high-voltage MOSFET (or IGBT) according to the present invention.

Since the active and termination regions are formed in the shape of a closed-loop containing the concentric alternating P and N pillars, the source (emitter) region may be formed in the active region in the shape of a closed-loop and the gate electrode may also be formed in the shape of a closed-loop.

As described above, unlike in the conventional art, charge balance is achieved throughout the entire active and termination regions, resulting in improved breakdown characteristics.

While the present invention has been particularly shown and described with reference to exemplary embodiments thereof, it will be understood by those of ordinary skill in the art that various changes in form and detail may be made therein without departing from the spirit and scope of the present invention as defined by the following claims.

What is claimed is:

1. A high-voltage semiconductor device comprising:
an active region including N pillars of N conductivity type and P pillars of P conductivity type,
wherein the N pillars and the P pillars are arranged alternately in a direction from a center portion of the active region to an outer portion thereof to encircle each other in a horizontal direction.

2. The device of claim 1, wherein the center portion of the active region includes only an N region of N conductivity type.

3. The device of claim 1, wherein the center portion of the active region includes only a P region of P conductivity type.

4. The device of claim 1, wherein the N and P pillars are closed.

5. The device of claim 1, wherein the N and P pillars are cylindrical except in the center portion.

6. The device of claim 1, wherein the N and P pillars are polygonal except in the center portion.

7. The device of claim 1, wherein the N and P pillars are rectangular or hexagonal pillars.

8. The device of claim 1, wherein the N and P pillars are substantially rectangular and have curved beveled edge portions.

9. The device of claim 1, wherein an N charge quantity in the N pillars is balanced with a P charge quantity in the P pillars.

10. The device of claim 2, wherein a first P pillar encircles and is in contact with a first N pillar, a second N pillar encircles and is in contact with the first P pillar, and a second P pillar encircles and is in contact with the second N pillar, and each of the first and second P pillars is divided into an inner P pillar and an outer P pillar by a center axis thereof, and a sectional area ratio Aₙ/Aₚ between a sectional area Aₙ of the second N pillar and a sum Aₚ of a sectional area of the inner P pillar of the second P pillar and a sectional area of the outer P pillar of the first P pillar is constant.

11. The device of claim 10, wherein a third P pillar encircles and is in contact with the N region in the center portion, the P pillar being divided into an inner P pillar and outer P pillar by a center axis thereof, the inner P pillar of the third P pillar being in contact with the N region, and a sectional area ratio A_{nc}/A_{pc} between a sectional area A_{nc} of the N region in the center portion and a sectional area A_{pc} of the inner P pillar of the third P pillar is equal to the sectional area ratio Aₙ/Aₚ.

12. The device of claim 3, wherein a first N pillar encircles and is in contact with a first P pillar, a second P pillar encircles and is in contact with the first N pillar, and a second N pillar encircles and is in contact with the second P pillar, and each of the first and second N pillars is divided into an inner N pillar and an outer N pillar by a center axis thereof, and a sectional area ratio Aₚ/Aₙ between a sectional area Aₚ of the second P pillar and a sum Aₙ of a sectional area of the inner N pillar of the second N pillar and a sectional area of the outer N pillar of the first N pillar constant.

13. The device of claim 12, wherein a third N pillar encircles and is in contact with the P region in the center portion, the N pillar being divided into an inner N pillar and outer N pillar by a center axis thereof, the inner N pillar of the third N pillar being in contact with the P region, and a sectional area ratio A_{pc}/A_{nc} between a sectional area A_{pc} of the P region in the center portion and a sectional area A_{nc} of the inner N pillar of the third N pillar is equal to the sectional area ratio Aₚ/Aₙ.

14. The device of claim 1, wherein a concentration of N conductivity dopants in the N pillars is identical to a concentration of P conductivity dopants in P pillars, and a sectional area ratio between a sectional area of the N pillars and a sectional area of the P pillars is 1.

15. The device of claim 1, wherein a concentration of N conductivity dopants in the N pillars is different from a concentration of P conductivity dopants in the P pillars, and a sectional area ratio between a sectional area of the N pillars and a sectional area of the P pillars is inversely proportional to the concentration ratio between the concentration of N conductivity type dopants in the N pillars and the concentration of P conductivity dopants in the P pillars.

16. The device of claim 14, wherein the N and P pillars have the same radial width.

17. The device of claim 1, further comprising a termination region surrounding the active region and including alternating arranged N pillars of N conductivity type and P pillars of P conductivity type, wherein the N pillars and the P pillars in the termination region encircle each other in a horizontal direction.

18. The device of claim 17, wherein each of the P pillars in the termination region is divided into an inner P pillar and an outer P pillar by a center axis thereof, and a sectional area ratio Aₙₜ/Aₚₜ between a sectional area Aₙₜ of each of the N pillars and a sum Aₚₜ of a sectional area of the inner P pillar surrounded by the each of the N pillars and a sectional area of the outer P pillar surrounding the each of the N pillars is different from the sectional area ratio Aₙ/Aₚ in the active region.

19. A high-voltage semiconductor device comprising:
a semiconductor substrate;
a voltage sustaining layer over the semiconductor substrate, the voltage sustaining layer comprising an active region including N pillars of N conductivity type and P pillars of P conductivity type, the N pillars and the P pillars being arranged alternately in a direction from a center portion of the active region to an outer portion thereof to encircle each other in a horizontal direction;
a first impurity region of a first conductivity type formed in an upper portion of the voltage sustaining layer;
a second impurity region of a second conductivity type formed in the first impurity region;
a first electrode making electrical contact to the first and second impurity regions; and
a second electrode making electrical contact to the semiconductor substrate.

20. The device of claim 19, wherein the device is a MOSFET.

21. The device of claim 19, wherein the device is an IGBT (insulated gate bipolar transistor).

22. The device of claim 19, wherein the center portion of the active region includes only an N region of N conductivity type.

23. The device of claim 19, wherein the center portion of the active region includes only a P region of P conductivity type.

24. The device of claim 19, wherein the N and P pillars are closed.

25. The device of claim 19, wherein the N and P pillars are cylindrical except in the center portion.

26. The device of claim 19, wherein the N and P pillars are polygonal except in the center portion.

27. The device of claim 19, wherein the N and P pillars are rectangular or hexagonal pillars.

28. The device of claim 19, wherein the N and P pillars are substantially rectangular and have curved beveled edge portions.

29. The device of claim 19, wherein an N charge quantity in the N pillars is balanced with a P charge quantity in the P pillars.

30. The device of claim 22, wherein a first P pillar encircles and is in contact with a first N pillar, a second N pillar encircles and is in contact with the first P pillar, and a second P pillar encircles and is in contact with the second N pillar, and each of the first and second P pillars is divided into an inner P pillar and an outer P pillar by a center axis thereof, and a sectional area ratio Aₙ/Aₚ between a sectional area Aₙ of the second N pillar and a sum Aₚ of a sectional area of the inner P pillar of the second P pillar and a sectional area of the outer P pillar of the first P pillar is constant.

31. The device of claim 30, wherein a third P pillar encircles and is in contact with the N region in the center portion, the P pillar being divided into an inner P pillar and outer P pillar by a center axis thereof, the inner P pillar of the third P pillar being in contact with the N region, and a sectional area ratio A_{nc}/A_{pc} between a sectional area A_{nc} of the N region in the center portion and a sectional area A_{pc} of the inner P pillar of the third P pillar is equal to the sectional area ratio Aₙ/Aₚ.

32. The device of claim 23, wherein a first N pillar encircles and is in contact with a first P pillar, a second P pillar encircles and is in contact with the first N pillar, and a second N pillar encircles and is in contact with the second P pillar, and each of the first and second N pillars is divided into an inner N pillar and an outer N pillar by a center axis thereof, and a sectional area ratio Aₚ/Aₙ between a sectional area Aₚ of the second P pillar and a sum Aₙ of a sectional area of the inner N pillar of the second N pillar and a sectional area of the outer N pillar of the first N pillar constant.

33. The device of claim 32, wherein a third N pillar encircles and is in contact with the P region in the center portion, the N pillar being divided into an inner N pillar and outer N pillar by a center axis thereof, the inner N pillar of the third N pillar being in contact with the P region, and a sectional area ratio A_{pc}/A_{nc} between a sectional area A_{pc} of the P region in the center portion and a sectional area A_{nc} of the inner N pillar of the third N pillar is equal to the sectional area ratio Aₚ/Aₙ.

34. The device of claim 19, wherein a concentration of N conductivity dopants in the N pillars is identical to a concentration of P conductivity dopants in P pillars, and a sectional area ratio between a sectional area of the N pillars and a sectional area of the P pillars is 1.

35. The device of claim 19, wherein a concentration of N conductivity dopants in the N pillars is different from a concentration of P conductivity dopants in the P pillars, and a sectional area ratio between a sectional area of the N pillars and a sectional area of the P pillars is inversely proportional to the concentration ratio between the concentration of N conductivity type dopants in the N pillars and the concentration of P conductivity dopants in the P pillars.

36. The device of claim 34, wherein the N and P pillars have the same radial width.

37. The device of claim 19, further comprising a termination region surrounding the active region and including alternating arranged N pillars of N conductivity type and P pillars of P conductivity type, wherein the N pillars and the P pillars in the termination region encircle each other in a horizontal direction.

38. A semiconductor power device comprising:
an active region; and
N regions of N conductivity type and P regions of P conductivity type alternately arranged in the active region,
wherein the N regions and the P regions encircle one another in a substantially concentric fashion.

39. The device of claim 38 wherein the semiconductor power device comprises an N-channel transistor, and no current flows through the P regions when the N-channel transistor is in an on state.

40. The device of claim 38 wherein the semiconductor power device comprises an P-channel transistor, and no current flows through the N regions when the P-channel transistor is in an on state.

41. The device of claim 38 further comprising:
a voltage sustaining layer extending over a substrate, the N regions and P regions being formed in the voltage sustaining layer;
a plurality of well regions of a first conductivity type in an upper portion of the voltage sustaining layer; and
source regions of a second conductivity type in the well regions.

42. The device of claim 41 further comprising:
gate trenches extending into the voltage sustaining layer adjacent to the source regions and the well regions;
a dielectric layer lining the gate trench sidewalls and bottom; and
a gate electrode in the gate trench.

43. The device of claim 41 further comprising:
a plurality of planar gates extending over the voltage sustaining layer, each planar gate overlapping at least one source region and at least one well region, each planar gate being insulting from its underlying regions by a dielectric layer.
